(19) United States
(12) Patent Application Publication
(10) Pub. No.: US 2016/0052651 A1
(43) Pub. Date: Feb. 25, 2016

(54) FILL ON DEMAND AMPOULE

(71) Applicant: Lam Research Corporation, Fremont, CA (US)

(72) Inventors: Tuan Nguyen, Tualatin, OR (US); Eashwar Ranganathan, Tigard, OR (US); Shankar Swaminathan, Beaverton, OR (US); Adrien LaVoie, Newberg, OR (US); Chloe Baldasseroni, Portland, OR (US); Frank L. Pasquale, Tualatin, OR (US); Purushottam Kumar, Hillsboro, OR (US); Jun Qian, Tualatin, OR (US); Hu Kang, Tualatin, OR (US)

(21) Appl. No.: 14/516,452

(22) Filed: Oct. 16, 2014

Related U.S. Application Data
(60) Provisional application No. 62/040,974, filed on Aug. 22, 2014.

(51) Int. Cl. B65B 1/08; C23C 16/458

(52) U.S. Cl. CPC B65B 1/08; C23C 16/458

(57) ABSTRACT

Methods and apparatus for use of a fill on demand ampoule are disclosed. The fill on demand ampoule may refill an ampoule with precursor concurrent with the performance of other deposition processes. The fill on demand may keep the level of precursor within the ampoule at a relatively constant level. The level may be calculated to result in an optimum head volume. The fill on demand may also keep the precursor at a temperature near that of an optimum precursor temperature. The fill on demand may occur during parts of the deposition process where the agitation of the precursor due to the filling of the ampoule with the precursor minimally effects the substrate deposition. Substrate throughput may be increased through the use of fill on demand.

### CROSS-REFERENCE TO RELATED APPLICATIONS

This application claims priority benefit under 35 U.S.C. §119(e) to U.S. Provisional Application No. 62/040,974, filed Aug. 22, 2014, titled “FILL ON DEMAND AMPOULE,” which is hereby incorporated by reference in its entirety.

### BACKGROUND

Certain substrate processing operations may utilize precursor. The precursor may be contained in an ampoule. Consistent head volume and consistent precursor temperature may be desired to ensure the uniformity of substrates processed. Additionally, agitation of the precursor from refilling may be undesirable when substrates are processed. Finally, refill times may affect throughput and high throughput may be desired.

### SUMMARY

In certain implementations, a method for refilling an ampoule of a substrate processing apparatus may be detailed. The method may include: (a) determining that an ampoule refill start condition is met, wherein the ampoule refill start condition comprises determining that the substrate processing apparatus is or is about to enter a phase during which agitation of the precursor caused by refilling the ampoule with the precursor would have a minimal effect on the consistency of substrates processed by the substrate processing apparatus, (b) refilling the ampoule with precursor, wherein refilling the ampoule with the precursor is performed concurrent with at least one other substrate processing operation, (c) determining that an ampoule refill stop condition is met, and (d) ceasing the refilling of the ampoule with the precursor.

In some such implementations of the method, the phase during which agitation of the precursor caused by filling the ampoule with the precursor would have a minimal effect on the consistency of substrates processed by the substrate processing apparatus in (a) may be a phase when precursor is not delivered to a substrate processing chamber, where the substrate processing chamber is configured to receive a substrate and deliver precursor to the substrate.

In some other or additional implementations of the method, the ampoule refill start condition may include determining that a sequence of deposition operations has been completed on substrates contained in the substrate processing apparatus. In some such implementations, the sequence of deposition operations may be deposition operations associated with Atomic Layer Deposition.

In some other or additional implementations of the method, the ampoule fill start condition may include determining that the precursor volume is below a threshold volume. In some such implementations, the threshold volume may be a precursor volume less than about 50% of the total ampoule volume.

In some other or additional implementations of the method, the ampoule fill start condition may include determining that setup for deposition operations is currently being performed.

In some other or additional implementations of the method, the at least one other substrate processing operation that is performed concurrent with filling the ampoule may include a wafer indexing operation.

In some other or additional implementations of the method, the at least one other substrate processing operation that is performed concurrent with filling the ampoule may include a temperature soak of the precursor and/or the substrate.

In some other or additional implementations of the method, the at least one other substrate processing operation that is performed concurrent with filling the ampoule may include a pump to base operation.

In some other or additional implementations of the method, the ampoule fill stop condition may be selected from the group consisting of: determining that an ampoule full sensor has been triggered, determining that an ampoule fill timer has expired, or determining that an ampoule fill stop has been triggered. In some such implementations, the ampoule full sensor may be triggered when the ampoule has a precursor volume exceeding about 80% of the total ampoule volume. In some other such implementations, the ampoule full sensor may be triggered when the ampoule has a precursor volume within a range of between about 70-100% of the total ampoule volume. In some other such implementations, the ampoule fill timer may be a period of time less than about 45 seconds. In some other such implementations, the ampoule fill stop may be triggered before one or more of: charging a flow path of the substrate processing apparatus with precursor, and performing a sequence of deposition operations on the substrate.

In some other or additional implementations, the method may further include, after (d), charging a flow path of the substrate processing apparatus with precursor.

In some other or additional implementations, the method my further include, after (d), performing a sequence of deposition operations on the substrate.

In certain implementations, a precursor refill system may be detailed. The precursor refill system may include an ampoule and one or more controllers. The ampoule may be configured to contain precursor, be a component of a substrate processing apparatus, and be fluidically connected to a precursor delivery system and a precursor source. The one or more controllers may be configured to: (a) determine that an ampoule fill start condition is met, where the ampoule fill start condition includes determining that the substrate processing apparatus is or is about to enter a phase during which agitation of the precursor caused by filling the ampoule with the precursor would have a minimal effect on the consistency of substrates processed by the substrate processing apparatus, (b) cause the ampoule to be filled with precursor from the precursor source, where filling the ampoule with the precursor is performed concurrent with at least one other substrate processing operation, (c) determine that an ampoule fill stop condition is met, and (d) cease filling the ampoule with the precursor.

In some such implementations of the substrate processing apparatus, the ampoule and the precursor source may be fluidically connected via a first flow path, the first flow path may include a valve, filling the ampoule with precursor may include opening the valve, and ceasing filling the ampoule with precursor may include closing the valve.

In some other or additional such implementations of the substrate processing apparatus, the ampoule and the precursor delivery system may be fluidically connected via a second flow path, the second flow path may include a valve, and the phase during which agitation of the precursor caused by filling the ampoule with the precursor would have a minimal effect on the consistency of substrates in (a) may include a phase when the valve on the second flow path is closed.

In some other or additional such implementations of the substrate processing apparatus, the substrate processing apparatus may further include a deposition chamber and a substrate processing station contained within the deposition chamber, where the substrate processing station may include a substrate holder configured to receive a substrate and the precursor delivery system may be configured to deliver precursor during processing of the substrate received by the substrate processing station.

These and other features of the invention will be described in more detail below with reference to the drawings.

### BRIEF DESCRIPTION OF THE DRAWINGS

FIG. 1A shows a schematic representation of an example substrate processing apparatus with a fill on demand ampoule.

FIG. 1B shows a schematic representation of another example substrate processing apparatus with a fill on demand ampoule.

FIG. 2 is a process flow diagram detailing an example deposition process operation utilizing a fill on demand ampoule.

FIG. 3 is a process flow diagram detailing an algorithm to control an example fill on demand ampoule.

FIG. 4A shows a step in substrate processing for the example substrate processing apparatus of FIG. 1A.

FIG. 4B shows another step in substrate processing for the example substrate processing apparatus of FIG. 1A.

FIG. 4C shows an additional step in substrate processing for the example substrate processing apparatus of FIG. 1A.

FIG. 4D shows a further step in substrate processing for the example substrate processing apparatus of FIG. 1A.

FIG. 5 is a comparison of substrate processing results for substrate processing with fill on demand versus substrate processing without fill on demand.

### DETAILED DESCRIPTION

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale unless specifically indicated as being scaled drawings.

It is to be understood that, as used herein, the term “semiconductor wafer” may refer both to wafers that are made of a semiconductor material, e.g., silicon, and wafers that are made of materials that are not generally identified as semiconductors, e.g., dielectrics and/or conductors, but that typically have semiconductor materials provided on them. Silicon on insulator (SOI) wafers are one such example. The apparatuses and methods described in this disclosure may be used in the processing of semiconductor wafers of multiple sizes, including 200 mm, 300 mm, and 450 mm diameter semiconductor wafers.

Uniformity is an important factor in the processing of high quality semiconductor wafers. For example, the thickness and quality of a deposited layer should be uniform from wafer-to-wafer and within features of a wafer. In certain implementations of semiconductor processing, a liquid precursor may need to be evaporated before being deposited on a semiconductor wafer. The liquid precursor may be contained in an ampoule and a carrier gas, such as argon or other inert gasses, and may flow through the ampoule to carry evaporated precursor to a semiconductor processing chamber. Carrier gas may be either “pushed” (where gas is forced through the lines) or “pulled” (where gas is pulled through the lines, possibly via a vacuum) through the ampoule to carry the evaporated precursor. In certain deposition processes, such as Atomic Layer Deposition (ALD), wafer uniformity may benefit from a relatively constant head volume of gas within the ampoule as well as a constant precursor temperature. In certain such implementations, the targeted head volume may be a volume of about 20-30% of the ampoule volume. Thus, about 70-80% of the ampoule may be filled with precursor when the head volume is about 20-30% of the ampoule volume. Further, wafer uniformity may also benefit from a lack of precursor agitation resulting in uneven evaporation of the precursor. Finally, high wafer throughput is important in the manufacture of semiconductor wafers. Currently, ampoules are typically refilled through manual fill, automatic fill, simultaneous fill, or refilled during maintenance. However, none of the current techniques combine a fairly constant head volume and precursor temperature when used during deposition, lack of precursor agitation during deposition, and high wafer throughput.

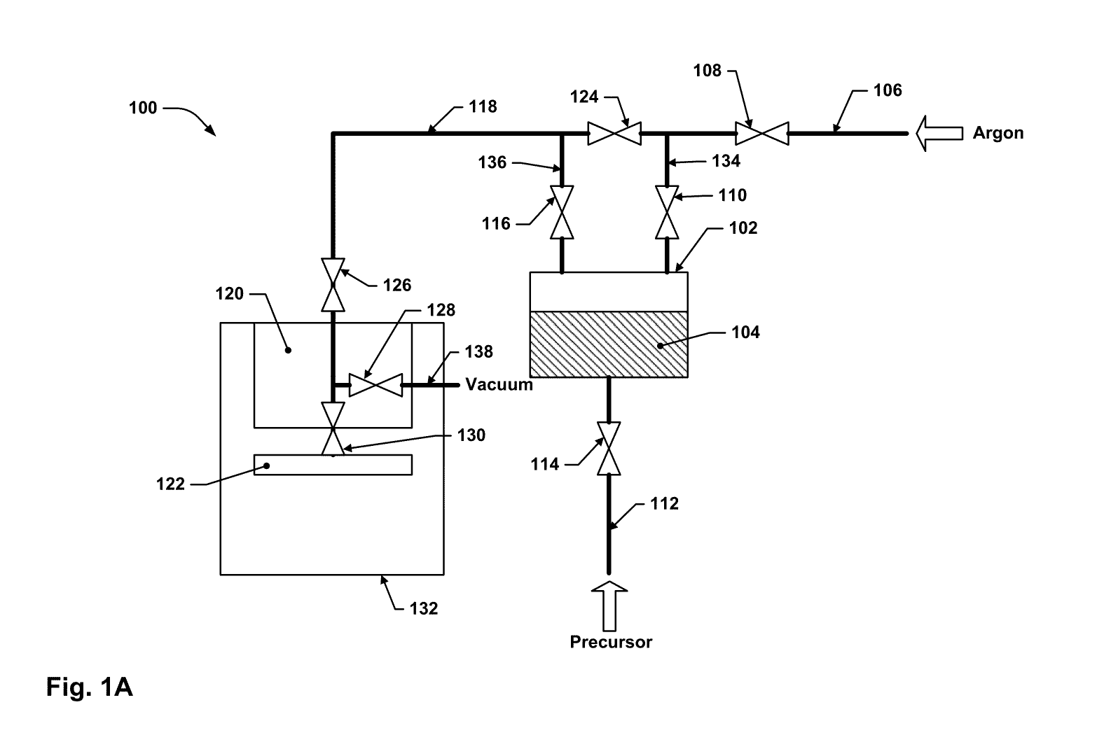

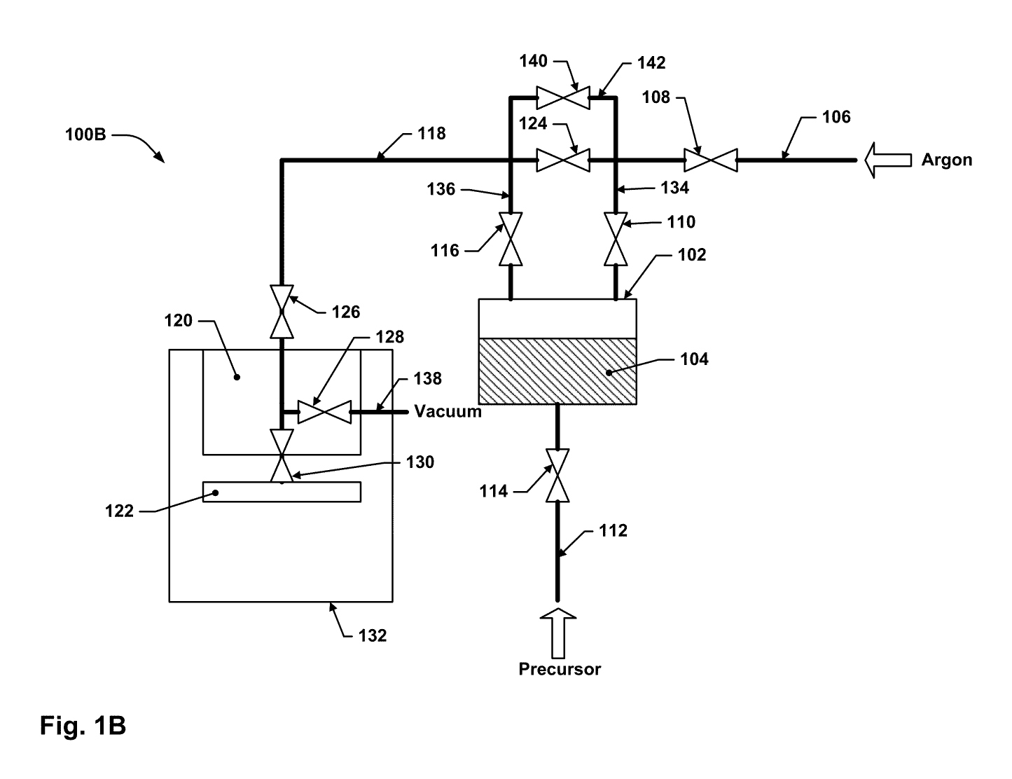

FIG. 1A shows a schematic representation of an example substrate processing apparatus with a fill on demand ampoule. FIG. 1A shows a substrate processing apparatus 100 with an ampoule 102 and a processing chamber 132.

The ampoule 102 contains precursor 104 in the representation shown in FIG. 1A. In certain implementations, the ampoule may have a volume of between about 600 mL to 3 L. In the implementation shown, the ampoule may be an ampoule of about 1.2 L. The precursor flows into the ampoule 102 through a flow path 112. A valve 114 controls the flow through precursor through the flow path 112. When the valve 114 is open, precursor may flow through the flow path 112 into the ampoule 102, filling the ampoule 102. When the valve 114 is closed, precursor may not flow into the ampoule 102. In the implementation shown, the flow path 112 is a flow path connected to the bottom of the ampoule 102. In other implementations, the flow path containing the precursor may be other configurations such as a dipstick and may fill the ampoule in areas other than from the bottom of the ampoule.

The processing chamber 132 includes a manifold 120 and a showerhead 122. Certain implementations may include more than one showerhead, such as two showerheads or four showerheads. In such implementations, the manifold may distribute fluids to the showerheads. Certain other implementations may replace the manifold with another device for the distribution of precursors, such as an injector. In other implementations, the processing chamber may not contain a manifold.

The showerhead 122 may be fluidically connected to the manifold 120 through a flow path 138 and a valve 130 may be installed on the flow path to control the flow of fluids from the manifold 120 to the showerhead 122. The showerhead 122 may distribute fluids that flow through the flow path 138 to process stations located in the processing chamber 132. The process stations may contain substrates. The process stations are not shown in FIG. 1A.

The manifold 120 may also be connected to a vacuum through other flow paths. The valve 128 may control the vacuum. In certain implementations, at most one of the valves 130 and 128 may be open at any given time. The vacuum may be used to allow for the continuous flow of carrier gas and/or precursor gas when the showerhead 122 is not ready to receive the flow of fluids.

Flow paths 118 and 136 connect the ampoule 102 to the manifold 120. A valve 126 is located on flow path 118. The valve 126 controls the flow of all fluids to the manifold 120; when the valve 126 is closed, no fluids may flow to the manifold 120. Conversely, when the valve 126 is opened, fluids may flow to the manifold. Additionally, a valve 124 is also located on flow path 118. The valve 124 controls the flow of carrier gas to the valve 126.

A valve 116 is located on flow path 136. The valve 116 controls the flow of precursor gas from the ampoule 102 to the valve 126.

Flow path 106 connects the substrate processing apparatus 100 with a source of carrier gas. The flow of the carrier gas through the flow path 106 into the rest of the flow paths of the substrate processing apparatus 100 is controlled by a valve 108. If the valve 108 is closed, there may be no fluid flow through the substrate processing apparatus 100.

Flow path 134 connects the flow path 106 with the ampoule 102. A valve 110 located on flow path 134 controls the flow of carrier gas from the flow path 106 into the ampoule 102. After the carrier gas flows into the ampoule 102, it may mix with evaporated precursor to form the precursor gas.

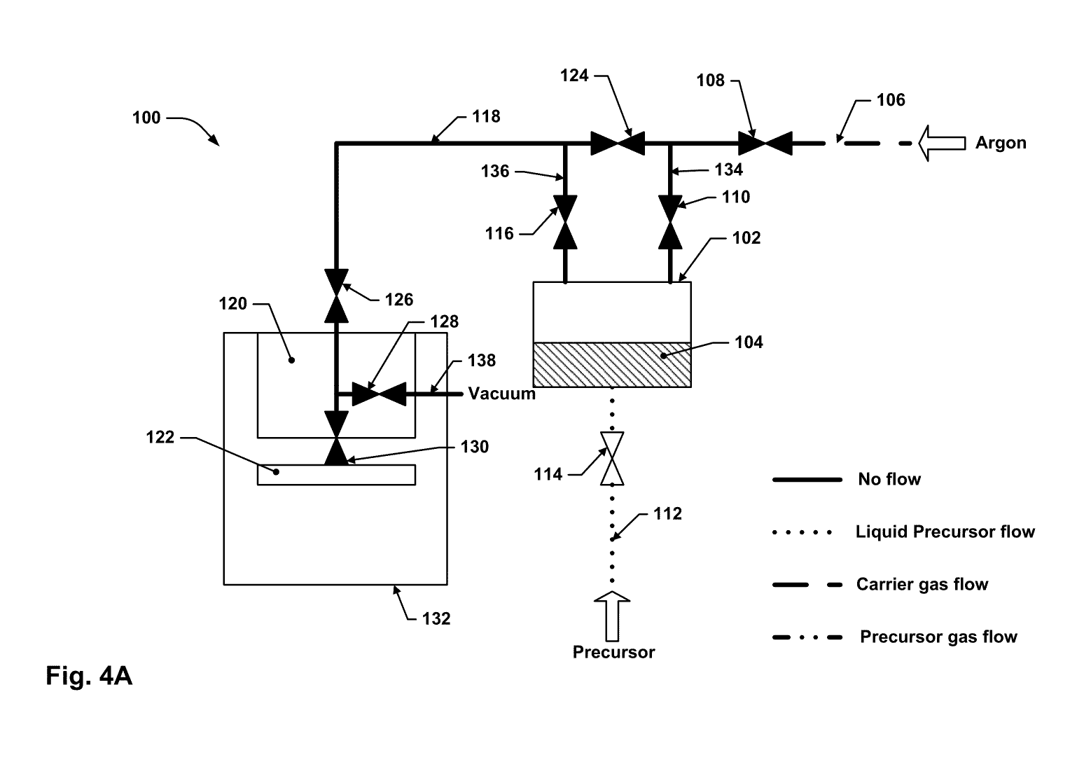

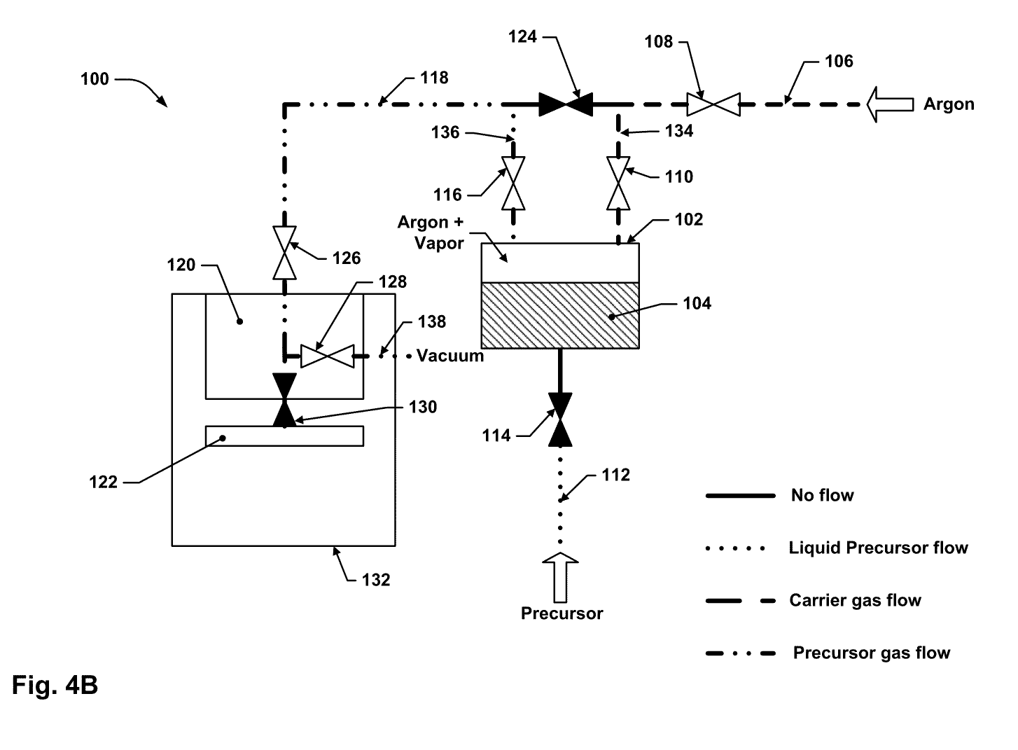

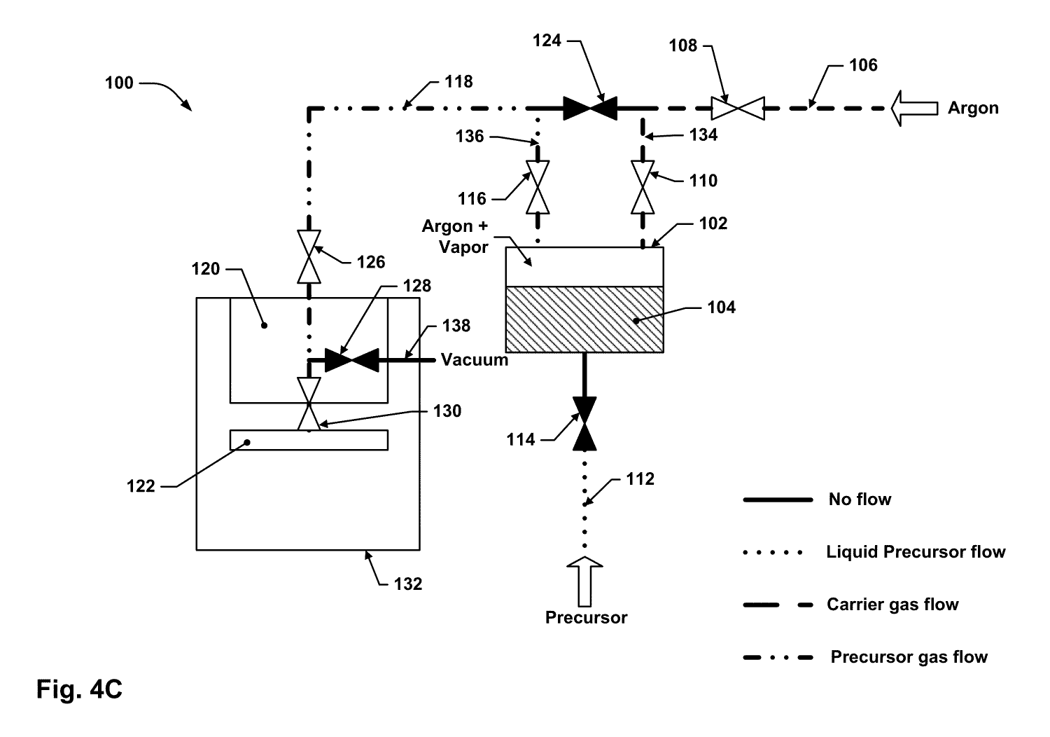

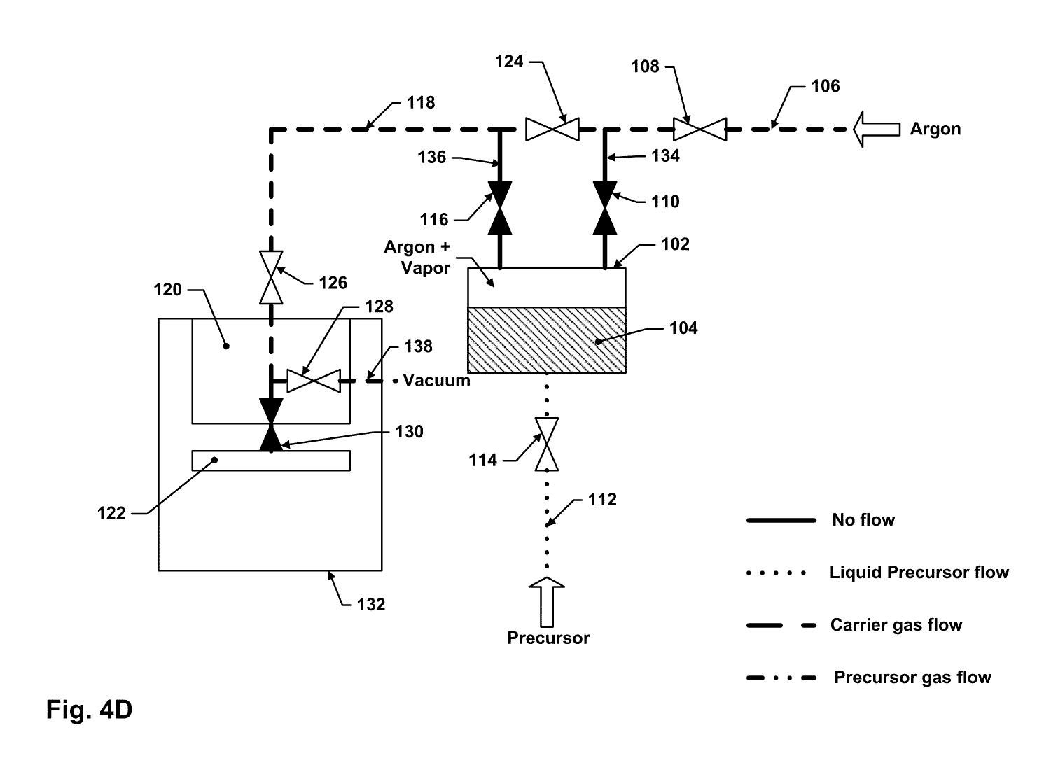

The flow of fluids through the substrate processing apparatus 100 may be controlled through the opening and closing of the various valves. Certain configurations of opened and closed valves will be discussed in greater detail in FIGS. 4A through 4D.

FIG. 1B shows a schematic representation of another example substrate processing apparatus with a fill on demand ampoule. The substrate processing apparatus 100B in FIG. 1B is similar to the substrate processing apparatus 100 in FIG. 1A. Substrate processing apparatus 100B includes an additional valve 140 connected by flow path 142. In the implementation of FIG. 100B shown in FIG. 1B, the flow path 142 and the valve 140 may offer an additional path for carrier gas to flow to the valve 126. In certain implementations, the flow path through the valve 124 may be used to flow carrier gas during operation of the substrate processing apparatus, while the flow path through the valve 140 may be used to flow carrier gas during maintenance of the substrate processing apparatus.

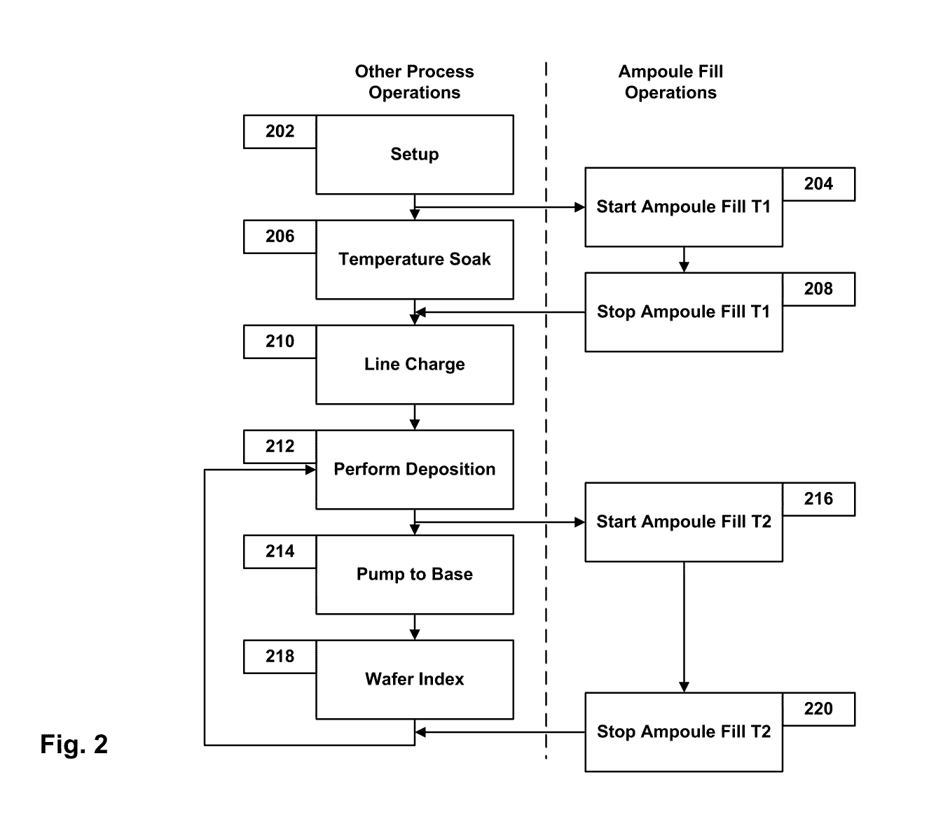

FIG. 2 is a process flow diagram detailing an example deposition process operation utilizing a fill on demand ampoule. FIG. 2 details ampoule fill operations and the timetable of the ampoule fill operations as compared to the rest of the process operations. In FIG. 2, ampoule fill operations are shown on the right side of the figure while other deposition process operations are shown on the left side. The process operation detailed in FIG. 2 may be an ALD processing operation, or may be other types of substrate processing operations.

In operation 202, setup of the process operation is carried out. Operation 202 includes many different tasks that are involved in the setting up of processing operations such as general checking of the apparatus, the lifting of pins, the loading of substrates, and the programming of operations.

After operation 202, operation 204 starts the filling of the ampoule. Operation 204 begins the initial filling of the ampoule. At the beginning of operation 204, the ampoule may be completely empty.

While the ampoule is being filled, temperature soak occurs in operation 206. The temperature soak may heat the precursor to bring it to a desired temperature, such as between about 20 to 100 degrees Celsius for certain precursors used in ALD, and/or it may heat the substrate prior to deposition. The temperature that the precursor is heated to may be dependent on the chemical composition of the precursor. Certain implementations may heat the precursor and/or the substrate from room temperature up to a higher temperature (e.g., a temperature between about 25-45 degrees Celsius). Other implementations may heat the precursor and/or the substrate from room temperature up to a temperature of between about 25-60 degrees Celsius while yet other implementations may heat the precursor and/or the substrate from room temperature up to an even higher temperature (e.g., up to about 80 degrees Celsius). The heat soaking of the precursor as it is being filled may result in a precursor that is at the optimum temperature for the precursor to evaporate to the desired amount. Additionally, heat soaking the precursor during the filling of the ampoule may allow for greater substrate throughput since two setup operations are being performed concurrently. Finally, since no carrier gas is being flowed through the ampoule to carry evaporated precursor gas, filling the ampoule during heat soak also may minimize the effect resulting from agitation of the precursor during filling.

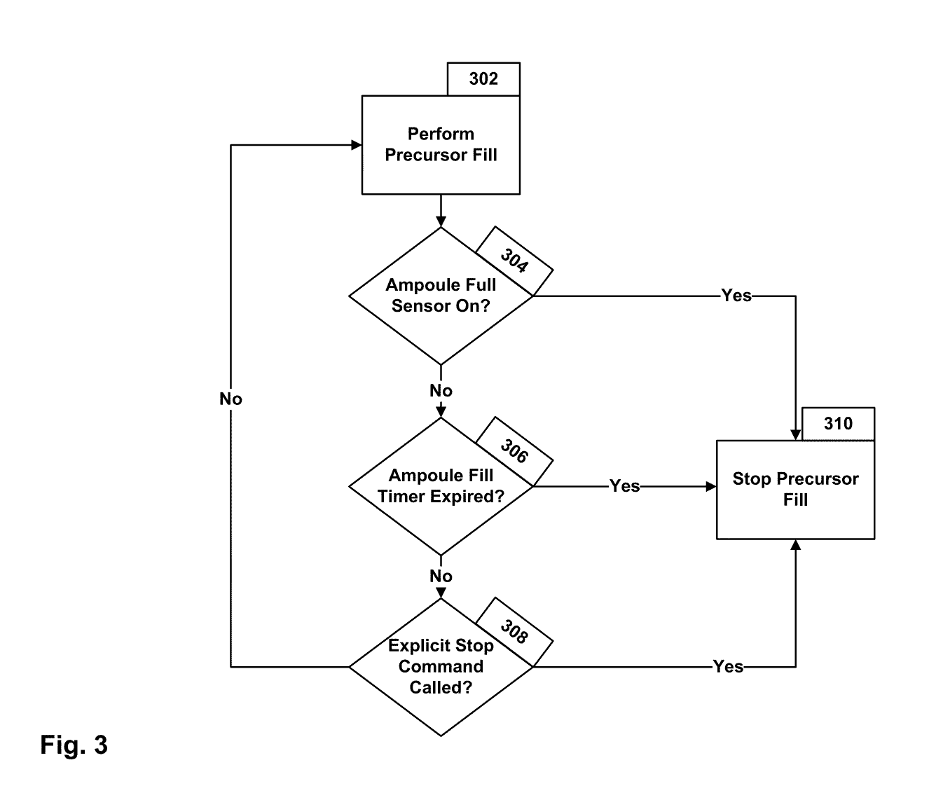

After the temperature soak of operation 206 is complete, but before the lines are charged in operation 210, the ampoule ceases being filled in operation 208. The ampoule may cease being filled due to a variety of different conditions. Such conditions are described in greater detail in FIG. 3. In certain implementations, the ampoule may initially be at a full level. In such implementations, the initial filling of the ampoule may be skipped.

In operation 210, line charge is performed. Line charge is the flow of gas through the flow paths of the substrate processing apparatus prior to delivering the precursor gas into the processing chamber. In other words, the lines leading to the chamber are charged to eliminate delay when the valves to the chamber are opened. For example, certain implementations may flow the carrier gas through various flow paths to carry precursor gas from the ampoule. The pre-flowing of such precursor gas may aid in having more consistent initial cycles of deposition by pre-charging the flow paths with precursor gas used in deposition such that when the valve to leading to the processing chamber is switched open, precursor gas is quicker to arrive in the processing chamber.

After the line charge in operation 210, deposition is performed in operation 212. Deposition performed in operation 212 may be a single cycle of deposition, or may be multiple cycles of deposition such as that performed during ALD.

After deposition is performed in operation 212, secondary ampoule filling is started in operation 216. The secondary ampoule filling in operation 216 may fill the ampoule back to a full level or may be designed to fill the ampoule until another stop fill condition is met. When a stop fill condition is met in operation 220, the second ampoule filing operation ceases. The secondary ampoule filling allows the ampoule to maintain a relatively consistent head volume, leading to greater wafer uniformity. During secondary ampoule filling, the ampoule may be heated to allow for more consistent precursor temperatures. In certain implementations such as the implementation described in FIG. 2, the secondary ampoule filling is timed to occur during a period when the agitation of the precursor resulting from the filling has a minimal effect on the substrate processing. In some implementations, such periods may be periods when no deposition is performed. In other implementations, deposition may be performed during such periods if the vapor pressure of the precursor is below a certain threshold. Precursors with low vapor pressures may be less sensitive to agitation from refilling and so may be more suitable to be refilled while deposition is performed. For example, precursors with a vapor pressure less than about 1 Torr are precursors that may be refilled during deposition. In certain implementations, the amount of precursor refilled during any single operation of secondary ampoule filling may be less than about 40% of the total ampoule volume, such as less than about 20%, less than about 10%, less than about 5%, or less than about 2% of the total ampoule volume.

While the secondary ampoule filling is performed, other process operations are still being performed, such as pump to base and wafer indexing. In operation 214, pump to base is performed. Pump to base is a process of evacuating a chamber to a base pressure provided by a vacuum pump. The process removes residual materials from the substrate processing chamber through, for example, vacuum ports in the processing chamber.

In operation 218, wafer indexing is performed. Wafer indexing is the transfer and orientation of substrates to an additional process station within the substrate processing chamber. Wafer indexing may be performed when the substrate processing chamber has multiple processing stations. In certain implementations, such as implementations involving a processing chamber with only one processing station, wafer indexing may not be performed.

After wafer indexing in operation 218, the process may proceed back to operation 212 and perform deposition again until all require deposition has been performed. Ampoule filling may be performed between each round of deposition.

FIG. 3 is a process flow diagram detailing an algorithm to control an example fill on demand ampoule. In operation 302, a command is given to perform precursor fill. Operation 302 may correspond to operations 204 or 216 in FIG. 2. The command to perform the precursor fill may be given through logic contained in a controller. The controller may be a controller used to control other deposition operations of the substrate processing apparatus, or it may be a separate controller dedicated to controlling operations associated with the ampoule.

In some implementations, a controller is part of a system, which may be part of the examples described herein. Such systems may comprise semiconductor processing equipment, including a processing tool or tools, chamber or chambers, a platform or platforms for processing, and/or specific processing components (a wafer pedestal, a gas flow system, an ampoule etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, refilling of ampoules, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Referring back to FIG. 3, once the command is given to perform the precursor fill, precursor begins to fill the ampoule. While the precursor fill is performed, the controller may also concurrently perform operations 304, 306, and 308.

In operation 304, the controller checks to see if the ampoule full sensor is on. The ampoule may contain a level sensor such as a discrete level sensor. The level sensor may be set to detect a certain precursor level within the ampoule such as the full level. Such a precursor full level may be calculated to result in an ampoule that contains an optimum head volume. In certain implementations, the full level may be a threshold volume calculated to arrive at the optimum head volume. Such threshold volumes may be, for example, a volume of precursor of around about 70-80% of the total volume of the ampoule such as about 75% of the total volume of the ampoule. In other implementations, the threshold volume may be a range of volumes. In such implementations, a precursor volume falling within the range may satisfy the full condition. In certain such implementations, subsequent secondary ampoule fillings may be adjusted based on the detected precursor volume. For example, the stop conditions of the subsequent secondary ampoule fillings may be adjusted.

In certain other implementations, the level sensor may report a low level. The low level may be reported when the volume of the precursor within the ampoule is below a threshold percentage of the ampoule volume. In such implementations, the threshold volume may be a volume of less than about 50% of the ampoule volume. In such implementations, the substrate processing apparatus may stop the processing of substrates when the level sensor reports a low level. In certain implementations, the substrate processing apparatus may finish all deposition cycles in a sequence of substrate deposition operations before stopping the substrate processing to refill the ampoule.

In operation 306, the controller checks to see if the ampoule fill timer has expired. The ampoule fill timer may be a timer set in the controller such that the ampoule fill process is performed for only a duration close to the duration that would be required to fill the ampoule to the full level. In certain implementations, the fill timer may be a duration slightly longer than the time required to fill the ampoule to the full level in order to introduce some safety factor. In other implementations, the ampoule fill timer may be much longer than the duration required to fill the ampoule to fill. In such implementations, the fill timer duration may be selected to allow the best opportunity to fill the ampoule to a full level and the ampoule full sensor may be relied upon as the primary mechanism to prevent overfilling of the ampoule.

In certain implementations, the fill timer for the initial fill and the secondary fill may be different. In such implementations, the initial fill timer may be, for example, 45 seconds or less, while the secondary fill timer may be, for example, between 5 to 10 seconds. In other implementations, the fill timer may be adjusted based on a correction factor. The correction factor may be a factor to account for the differences in pressures of the refill lines of various different substrate processing apparatus. Thus, a substrate processing apparatus that has a high refill line pressure may have a low correction factor resulting in a shorter fill timer, while a substrate processing apparatus that has a low refill line pressure may have a high correction factor resulting in a longer fill timer. The refill line pressure may vary based on inherent properties of the substrate processing apparatus, or it may vary based on operators' experience with a particular piece of equipment. For example, the refill line pressure may be decreased if a further decrease in precursor agitation is desired. In addition, the correction factor may account for any variation upstream of a pressure indicator within the precursor refill line. Factors that may affect the line pressure include the diameter and length of the refill line.

In certain implementations, the secondary fill timer may stay constant regardless of the conditions detected during the initial fill. In other implementations, the secondary fill timer may be adjusted depending on conditions detected during the initial fill. For example, if, during initial fill, the ampoule full sensor was never detected to be on, the duration of the secondary fill timer may be lengthened to allow for a greater likelihood of the ampoule reaching a full level during the secondary fill operation.

In operation 308, the controller checks to see if an explicit stop command has been called. In certain implementations, an explicit stop command to cease filling the ampoule may be programmed into the controller before the performance of certain deposition steps, such as deposition steps where concurrent filling of the ampoule during performance of the steps may result in unacceptable agitation of the precursor. The explicit stop command may be a further safeguard against the failure of the ampoule full sensor and/or the ampoule fill timer. Additionally, the fill timer and/or the full volume may be user defined parameters in certain implementations. The explicit stop command may prevent errors in the user definition of the parameters from affecting the quality of substrate processing.

If the controller detects a “yes” result from any of operations 304, 306, or 308, the controller then proceeds to operation 310 and the precursor fill is stopped. If no “yes” result is detected from any of operations 304, 306, or 308, the controller may return to operation 302 and continue performing the precursor fill.

FIG. 4A shows a step in substrate processing for the example substrate processing apparatus of FIG. 1A. The step shown in FIG. 4A corresponds to operation 204 of FIG. 2. The substrate processing apparatus 100 shown in FIG. 4A, as well as FIGS. 4B-C, may be a substrate processing apparatus with a similar configuration to that of the substrate processing apparatus shown in FIG. 1A. In FIGS. 4A-D, solid lines represent flow paths with no flow, dotted lines represent flow paths with liquid precursor flow, broken lines represent flow paths with carrier gas flow, and broken and dotted lines represent flow paths with precursor gas flow.

In FIG. 4A, initial filling of the ampoule 102 is being performed. In the implementation shown in FIG. 4A, all valves except for valve 114 are closed. Valve 114 is open to allow the flow of the precursor into the ampoule 102. In other implementations, valves 108, 124, 126, and 128 may be open. The ampoule 102 may be heated in FIG. 4A in order to bring the precursor to a desired temperature to facilitate evaporation of the precursor.

FIG. 4B shows another step in substrate processing for the example substrate processing apparatus of FIG. 1A. The step shown in FIG. 4B corresponds to operation 210 of FIG. 2. In FIG. 4B, valve 114 is now closed as at least one of the conditions required to stop the filling of the precursor has been triggered.

In FIG. 4B, valves 108, 110, 116, and 126 are open to allow the substrate processing apparatus to pre-charge flow paths 118 and 136 with precursor gas flow. Since the showerhead 122 is not ready to receive the precursor gas flow in FIG. 2, the precursor gas that flows through flow paths 118 and 136 then flows through flow path 138 to a dump source. A continuous flow of precursor gas is supplied through flow paths 118 and 136 to ensure that there is a ready supply of precursor gas when the showerhead 122 is ready to receive the precursor gas.

In FIG. 4B, the precursor gas is a mixture of carrier gas and evaporated precursor. Carrier gas flows through flow path 106 and 134, which have open valves 108 and 110 respectively, to enter the ampoule 102. The ampoule contains evaporated precursor and the carrier gas mixes with the evaporated precursor to form the precursor gas. The precursor gas then flows out of the ampoule 102 via the flow path 136.

FIG. 4C shows an additional step in substrate processing for the example substrate processing apparatus of FIG. 1A. The step shown in FIG. 4C corresponds to operation 212 of FIG. 2. In FIG. 4C, valve 128 is now closed, but valve 130 is now open to allow the precursor gas to flow through the showerhead 122 and into the processing chamber 132.

FIG. 4D shows a further step in substrate processing for the example substrate processing apparatus of FIG. 1A. The step shown in FIG. 4D corresponds to operation 214 of FIG. 2. In FIG. 4D, valves 110 and 116 are closed, but valve 124 is open. Thus, there is no flow of precursor gas through the flow paths, but carrier gas may flow through flow paths 106 and 118. Additionally, valve 130 is now closed to prevent the flow of carrier gas into the showerhead 122. Valve 128 is now open to allow the flow of carrier gas to the dump source.

In FIG. 4D, valve 114 is open to allow the refilling of ampoule 102 with precursor. The refilling shown in FIG. 4D is a secondary precursor refill.

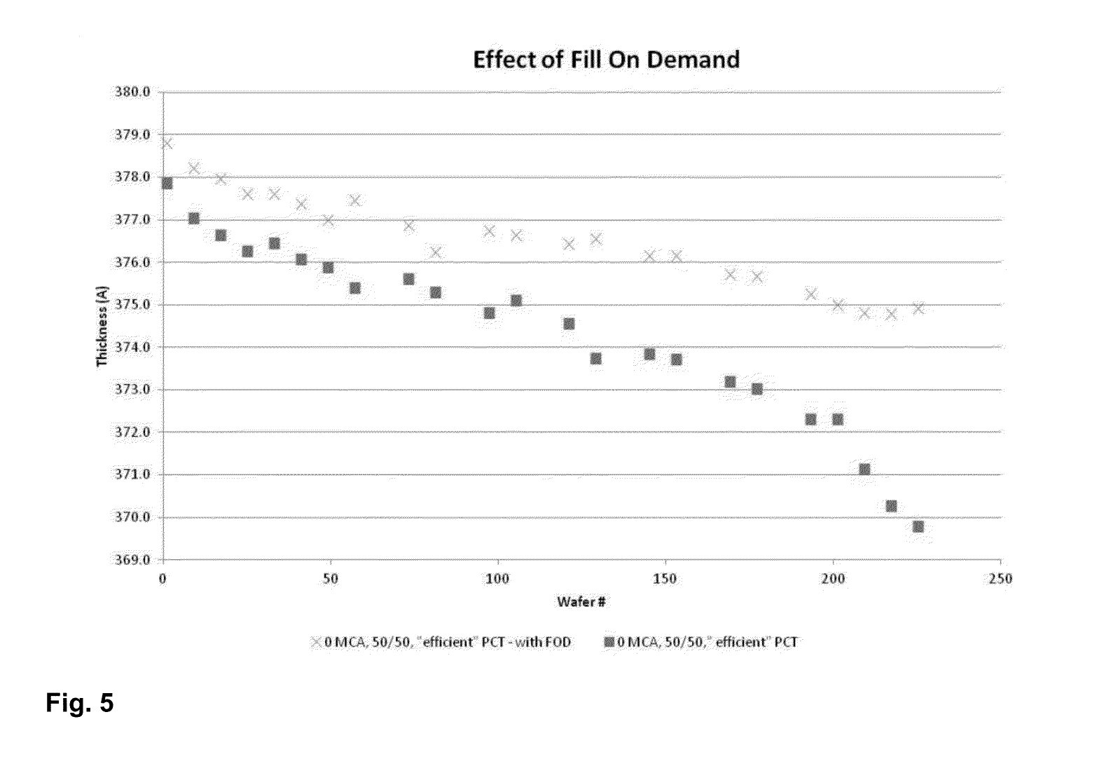

FIG. 5 is a comparison of substrate processing results for substrate processing with fill on demand versus substrate processing without fill on demand. In FIG. 5, the plots represented by “X” marks are deposition processes utilizing fill on demand, while the plots represented by square marks are deposition processes that do not utilize fill on demand.

As shown in FIG. 5, the deposition processes utilizing fill on demand have more consistent thicknesses while the deposition processes that do not utilize fill on demand have greater variances in their thicknesses. The deposition processes utilizing fill on demand show greater process uniformity than the deposition processes that do not utilize fill on demand.

What is claimed is:

1. A method for filling an ampoule of a substrate processing apparatus comprising:
(a) determining that an ampoule fill start condition is met, wherein the ampoule fill start condition comprises determining that the substrate processing apparatus is in or is about to enter a phase during which agitation of the precursor caused by filling the ampoule with the precursor would have a minimal effect on the consistency of substrates processed by the substrate processing apparatus;
(b) filling the ampoule with precursor, wherein filling the ampoule with the precursor is performed concurrent with at least one other substrate processing operation;
(c) determining that an ampoule fill stop condition is met; and
(d) ceasing the filling of the ampoule with the precursor.

2. The method of claim 1, wherein the phase during which agitation of the precursor caused by filling the ampoule with the precursor would have a minimal effect on the consistency of substrates processed by the substrate processing apparatus in (a) is a phase when precursor is not delivered to a substrate processing chamber, wherein the substrate processing chamber is configured to receive a substrate and deliver precursor to the substrate.

3. The method of claim 1, wherein the ampoule fill start condition includes determining that a sequence of deposition operations has been completed on substrates contained in the substrate processing apparatus.

4. The method of claim 3, wherein the sequence of deposition operations are deposition operations associated with Atomic Layer Deposition.

5. The method of claim 1, wherein the ampoule fill start condition includes determining that the precursor volume is below a threshold volume.

6. The method of claim 5, wherein the threshold volume is a precursor volume less than about 50% of the total ampoule volume.

7. The method of claim 1, wherein the ampoule fill start condition includes determining that setup for deposition operations is currently being performed.

8. The method of claim 1, wherein the at least one other substrate processing operation that is performed concurrent with filling the ampoule includes a wafer indexing operation.

9. The method of claim 1, wherein the at least one other substrate processing operation that is performed concurrent with filling the ampoule includes a temperature soak of the precursor and/or the substrate.

10. The method of claim 1, wherein the at least one other substrate processing operation that is performed concurrent with filling the ampoule includes a pump to base operation.

11. The method of claim 1, wherein the ampoule fill stop condition is selected from the group consisting of: determining that an ampoule full sensor has been triggered, determining that an ampoule fill timer has expired, or determining that an ampoule fill stop has been triggered.

12. The method of claim 11, wherein the ampoule full sensor has been triggered when the ampoule has a precursor volume exceeding about 80% of the total ampoule volume.

13. The method of claim 11, wherein the ampoule full sensor has been triggered when the ampoule has a precursor volume within a range of between about 70-100% of the total ampoule volume.

14. The method of claim 11, wherein the ampoule fill timer is a period of time less than about 45 seconds.

15. The method of claim 11, wherein the ampoule fill stop is triggered before one or more of:
charging a flow path of the substrate processing apparatus with precursor; and
performing a sequence of deposition operations on the substrate.

16. The method of claim 1, further comprising, after (d), charging a flow path of the substrate processing apparatus with precursor.

17. The method of claim 1, further comprising, after (d), performing a sequence of deposition operations on the substrate.

18. A precursor refill system comprising:
an ampoule configured to contain precursor, be a component of a substrate processing apparatus, and be fluidically connected to a precursor delivery system and a precursor source; and
one or more controllers configured to:
(a) determine that an ampoule fill start condition is met, wherein the ampoule fill start condition comprises determining that the substrate processing apparatus is or is about to enter a phase during which agitation of the precursor caused by filling the ampoule with the precursor would have a minimal effect on the consistency of substrates processed by the substrate processing apparatus;
(b) cause the ampoule to be filled with precursor from the precursor source, wherein filling the ampoule with the precursor is performed concurrent with at least one other substrate processing operation;
(c) determine that an ampoule fill stop condition is met; and
(d) cease filling the ampoule with the precursor.

19. The substrate processing apparatus of claim 18, wherein:
the ampoule and the precursor source is fluidically connected via a first flow path;
the first flow path includes a valve;
filling the ampoule with precursor includes opening the valve; and
ceasing filling the ampoule with precursor includes closing the valve.

20. The substrate processing apparatus of claim 18, wherein:
the ampoule and the precursor delivery system is fluidically connected via a second flow path;
the second flow path includes a valve; and
the phase during which agitation of the precursor caused by filling the ampoule with the precursor would have a minimal effect on the consistency of substrates in (a) includes a phase when the valve on the second flow path is closed.

21. The substrate processing apparatus of claim 18, further comprising:
a deposition chamber; and
a substrate processing station contained within the deposition chamber, wherein the substrate processing station includes a substrate holder configured to receive a substrate and the precursor delivery system is configured to deliver precursor during processing of the substrate received by the substrate processing station.
